(19) United States
(12) Patent Application Publication
(10) Pub. No.: US 2026/0012033 A1
(43) Pub. Date: Jan. 8, 2026

(54) SYSTEMS AND METHODS FOR CHARGING AND DISCHARGING MANAGEMENT OF ENERGY STORAGE DEVICES

(71) Applicant: XCHARGE ENERGY USA INC., Kyle, TX (US)

(72) Inventors: Junshuai WANG, Kyle, TX (US); Rui DING, Kyle, TX (US)

(73) Assignee: XCHARGE ENERGY USA INC., Kyle, TX (US)

(21) Appl. No.: 18/764,114

(22) Filed: Jul. 3, 2024

(51) Int. Cl. H02J 7/00; G06F 30/27; H01M 10/42; H01M 10/44; H01M 10/48

(52) U.S. Cl. CPC H02J 7/007182; G06F 30/27; H01M 10/425; H01M 10/443; H01M 10/486; H02J 7/0047; H02J 7/0068; H02J 7/007194; H01M 2010/4271

(57) ABSTRACT

A system and method for charging and discharging management of an energy storage device. The system includes an electrical signal collection circuit, a condition monitoring device, a processor, a gating mechanism, a control circuit, and a bidirectional switching power supply. The processor is configured to: in response to the energy storage device being in a charging state, determine a charging parameter based on a voltage signal and condition data of at least one battery core, send the charging parameter to the control circuit; in response to the energy storage device being in a discharging state, determine a discharging parameter based on the voltage signal of the at least one battery core, and the discharging load of at least one discharging port, send the discharging parameter to the control circuit, the discharging parameter including the target discharging battery core.

### TECHNICAL FIELD

The present disclosure relates to the field of energy storage batteries, and in particular, to a system and method for charging and discharging management of an energy storage device.

### BACKGROUND

A battery pack for energy storage is generally composed of a number of single batteries connected in series or in parallel to achieve designed voltage and capacity levels. However, due to differences in a system design, an operating environment, and performance of the batteries themselves, the battery pack may have a problem of inconsistent power during cycling, which not only affects a discharging energy of the batteries and drastically shortens a service life of the battery, but also causes an irreversible damage to the battery, such as overcharging or over-discharging.

There is therefore a need to provide an improved system and method for charging and discharging management of an energy storage device to rationally adjust charging and discharging parameters to ensure an overall operating life of the energy storage device and reduce a failure rate.

### SUMMARY

At least one embodiment of the present disclosure provides a system for charging and discharging management of an energy storage device. The system may include an electrical signal collection circuit, a state monitoring device, a processor, a gating mechanism, a control circuit, and a bidirectional switching power supply. The electrical signal collection circuit may be configured to collect a voltage signal of at least one battery core in the energy storage device. The state monitoring device may be configured to monitor state data of the at least one battery core, the state data including a temperature, a humidity, and a dust accumulation of environment where the at least one battery core is located. The processor may be configured to: in response to that the energy storage device is in a charging state, determine, based on the voltage signal and the state data of the at least one battery core, the charging parameter, and send the charging parameter to the control circuit, the charging parameter including a target charging battery core, and a charging voltage of the target charging battery core; in response to that the energy storage device is in a discharging state, determine, based on the voltage signal of the at least one battery core, and a discharging load of at least one discharging port, the discharging parameter, and send the discharging parameter to the control circuit, the discharging parameters including the target discharging battery core. The control circuit may be configured to send, based on the charging parameter, a first control command to the gating mechanism, and a first work command to the bidirectional switching power supply; or, send, based on the discharging parameter, a second control command to the gating mechanism, and a second work command to the bidirectional switching power supply. The gating mechanism may be configured to connect the target charging battery core to the bidirectional switching power supply based on the first control command; or, connect the target discharging battery core to the bidirectional switching power supply based on the second control command. The bidirectional switching power supply may be configured to supply power to the target charging battery core based on the first work command; or, discharge power by the target discharging battery core based on the second work command.

At least one embodiment of the present disclosure provides a method for charging and discharging management of an energy storage device, which is executed by a processor. The method may include: obtaining a voltage signal of at least one battery core; obtaining state data of the at least one battery core, the state data including a temperature, a humidity, and a dust accumulation of environment where the at least one energy storage device is located. The method may further include: in response to that the energy storage device is in a charging state, determining a charging parameter based on the voltage signal and state data of the at least one battery core, the charging parameter including a target charging battery core, and a charging voltage of the target charging battery core; and sending the charging parameter to a control circuit to cause the control circuit to send a first control command to a gating mechanism based on the charging parameter, such that the gating mechanism connects the target charging battery core with the bidirectional switching power supply based on the first control command, and sending the first work command to the bidirectional switching power supply, so that the bidirectional switching power supply supplies power to the target charging battery core based on the first work command; in response to that the energy storage device is in a discharging state, determining, based on the voltage signal of the at least one battery core and the discharging load of the at least one discharging port, a discharging parameter, the discharging parameter including a target discharging battery core; sending the discharging parameter to the control circuit to cause the control circuit to send a second control command to the gating mechanism based on the discharging parameter, such that the gating mechanism connects the target discharging battery core to the bidirectional switching power supply based on the second control command, and sending a second work command to the bidirectional switching power supply, so that the bidirectional switching power supply discharges the power supply by the target discharging battery core based on the second work command.

At least one it disclosure provides a computer-readable storage medium, the storage medium storing computer instructions, and a computer executing any of the method for charging and discharging management of an energy storage device when the computer reads the computer instructions in the storage medium.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, wherein:

FIG. 1 is a schematic diagram illustrating an application scenario of a system for charging and discharging management of an energy storage device according to some embodiments of the present disclosure;

FIG. 2 is a schematic diagram illustrating a structure of a gating mechanism according to some embodiments of the present disclosure;

FIG. 3 is a flowchart illustrating an exemplary method for charging and discharging management of an energy storage device according to some embodiments of the present disclosure;

FIG. 4 is a flowchart illustrating an exemplary process for determining a charging parameter according to some embodiments of the present disclosure; and

FIG. 5 is a flowchart illustrating an exemplary process for determining a target discharging battery core and a relay battery core according to some embodiments of the present disclosure.

### DETAILED DESCRIPTION

The accompanying drawings, which are required to be used in the description of the embodiments, are briefly described below. The accompanying drawings do not represent the entirety of the embodiments.

As used herein, “system,” “device,” “unit,” and/or “module” are used as a means of distinguishing between different levels of components, elements, parts, sections, or assemblies. However, these words may be replaced by other expressions if other words would accomplish the same purpose.

As indicated in the present disclosure, unless the context clearly suggests an exception, the words “one,” “a, “one,” and/or “the” do not refer specifically to the singular, but may also include the plural. Generally, the terms “including” and “comprising” suggest only the inclusion of clearly identified steps and elements. In general, these terms only suggest the inclusion of explicitly identified steps and elements that do not constitute an exclusive list, and the method or apparatus may also include other steps or elements.

When describing the operations performed in the embodiments of the present disclosure in terms of the steps, the order of the steps is interchangeable, the steps may be omitted, and other steps may be included in the course of the operations, if not otherwise specified.

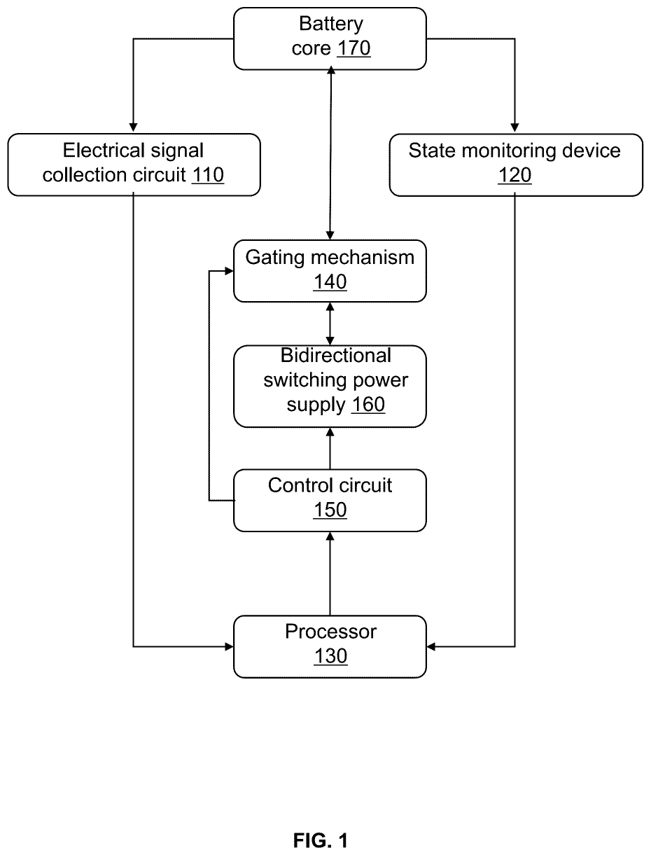

FIG. 1 is a schematic diagram illustrating an application scenario of a system for charging and discharging management of an energy storage device according to some embodiments of the present disclosure. In some embodiments, an application scenario 100 of the system for charging and discharging management of the energy storage device may include an electrical signal collection circuit 110, a state monitoring device 120, a processor 130, a gating mechanism 140, a control circuit 150, a bidirectional switching power supply 160, and a battery core 170.

The energy storage device refers to a device that stores electrical or other energies. For another example, the energy storage device may be a battery pack of a new energy vehicle. In some embodiments, the energy storage device may include a plurality of the battery cores 170. For example, the plurality of battery cores 170 may be combined together in series, in parallel, or in series-parallel connection to form the energy storage device may meet specific voltage and capacity requirements.

The battery core 170 refers to a unit that is capable of storing an electrical energy, as well as converting the electrical energy into an electrical current. In some embodiments, the battery core 170 may include a positive and negative material, an electrolyte, a diaphragm, etc.

The electrical signal collection circuit 110 may be configured to obtain a voltage signal from at least one battery core 170 in the energy storage device. In some embodiments, the electrical signal collection circuit 110 may be configured to monitor the voltage signal of the battery core 170. For instance, the electrical signal collection circuit 110 may include at least one small circuit board (e.g., including a circuitry for a voltmeter) connected to the positive and negative poles of the battery core 170 for a real-time voltage measurement of the battery core 170.

The state monitoring device 120 may be configured to monitor state data of at least one battery core 170. The state data refers to data that reflects state information of the battery core 170. For example, the state data may include a temperature, a humidity, and a dust accumulation of environment in which the battery core 170 is located. In some embodiments, the state monitoring device 120 may include a sensor (e.g., a temperature sensor, a humidity sensor, a dust sensor, etc.) deployed around the battery core 170. For example, the temperature sensor may be configured to measure a real-time temperature of the environment in which the battery core 170 is located, the humidity sensor may be configured to detect a humidity level of the environment in which the battery core 170 is located, and the dust sensor may be configured to monitor the dust accumulation of environment in which the battery core 170 is located.

The processor 130 may be configured to process data related to the system for charging and discharging management of the energy storage device. For example, in response to that the energy storage device is in a charging state, the processor 130 may determine a charging parameter based on the voltage signal and the state data of the at least one battery core 170, and send the charging parameter to the control circuit 150. The charging parameter may include a target charging battery core 170 and the charging voltage of the target charging battery core 170. For another problem, in response to that the energy storage device is in a discharging state, the processor 130 may determine, based on the voltage signal of the at least one battery core 170 and a discharging load of at least one discharging port, a discharging parameter, and send the discharging parameter to the control circuit 150. The discharging parameter may include a target discharging battery core 170.

In some embodiments, the processor 130 may be a single server or a server group. The server group may be centralized or distributed. In some embodiments, the processor 130 may be local or remote. In some embodiments, the processor 130 may be implemented on a cloud platform. Merely by way of example, the cloud platform may include a private cloud, a public cloud, a hybrid cloud, a community cloud, a distributed cloud, an internal cloud, a multi-tiered cloud, etc. or any combination thereof.

The control circuit 150 may be configured to send, based on the charging parameter, a first control command to the gating mechanism 140, and a first work command to the bidirectional switching power supply 160. Alternatively, the control circuit 150 may be configured to send, based on the discharging parameter, a second control command to the gating mechanism 140, and a second work command to the bidirectional switching power supply 160.

The gating mechanism 140 may be configured to connect the target charging battery core 170 with the bidirectional switching power supply 160 based on the first control command; or connect the target discharging battery core 170 with the bidirectional switching power supply 160 based on the second control command. In some embodiments, the gating mechanism 140 may be a switching matrix.

The bidirectional switching power supply 160 may be configured to supply power to the target charging battery core 170 based on the first work command; or, to discharge power by the target discharging battery core 170 based on the second work command.

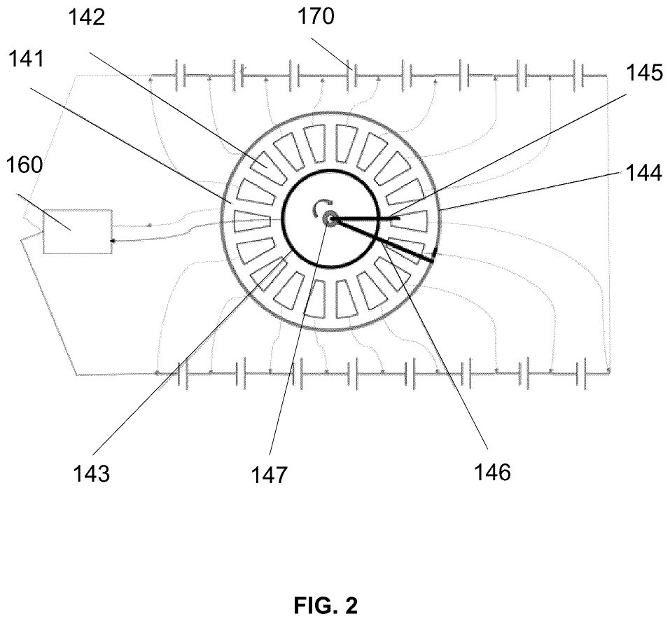

FIG. 2 is a schematic diagram illustrating a structure of a gating mechanism according to some embodiments of the present disclosure.

In some embodiments, as shown in FIG. 2, the gating mechanism 140 may include a gating disk 141, a motor, and an electronic connector (not shown in the figure).

The gating disk 141 may be configured to be electrically coupled to at least one battery core 170, and the electronic connector may be configured to be electrically coupled to the bidirectional switching power supply 160.

The motor may be configured to cause the electronic connector to cooperate with a specified position of the gating disk 141 in accordance with a control command (e.g., a first control command or a second control command) to enable connectivity between a target battery core (e.g., a target discharging battery core or a target charging battery core) and the bidirectional switching power supply 160.

In some embodiments, the motor may drive the electronic connector to rotate to a specified position of the gating disk 141, or the motor may drive the gating disk 141 such that the specified position of the gating disk 141 rotates to contact/connect to the electronic connector. Thereafter, the connectivity between the target battery core and the bidirectional switching power supply 160 may be realized.

In some embodiments, an output shaft of the motor may be connected to a rotor 147, and the rotor 147 may be transmissively connected to the electronic connector to drive the electronic connector. In some embodiments, the rotor 147 may be connected to a first pointer 145 and a second pointer 146. The electronic connector may include a first conductive slip ring 143, a second conductive slip ring 144, a first electrode, and a second electrode.

The conductive slip ring refers to a circular structure that conducts power. In some embodiments, the first electrode and the second electrode may be rotatably coupled to the first conductive slip ring 143 and the second conductive slip ring 144, respectively. In some embodiments, the first conductive slip ring 143 may be coaxial with the second conductive slip ring 144. In some embodiments, the first electrode may be electrically connected to one of the electrodes of the bidirectional switching power supply 160 via the first conductive slip ring 143, and the second electrode may be electrically connected to the other electrode of the bidirectional switching power supply 160 via the second conductive slip ring 144. In some embodiments, the first conductive slip ring 143 may be insulated from the second conductive slip ring 144. The first electrode may be insulated from the second electrode.

In some embodiments, the first electrode may be provided on the first pointer 145. The second electrode may be provided on the second pointer 146. In some embodiments, a diameter of the second conductive slip ring 144 may be greater than a diameter of the first conductive slip ring 143. A length of the second pointer 146 may be equivalent to a length of the first pointer 145.

The gating disk 141 refers to a disc or disc-like structure capable of insulation. For example, a disc-like structure made of a PCB board may be used. In some embodiments, a plurality of conductive regions 142 may be provided on an upper end surface of the gating disk 141.

The conductive region 142 refers to a region capable of conducting power and having a certain area. In some embodiments, the conductive region 142 may be made of a conductive material. In some embodiments, a plurality of conductive regions 142 may be arranged in an annular distribution in a circumferential direction of the gating disk 141. Adjacent two conductive regions may be insulated from each other. In some embodiments, the first electrode and the second electrode may be simultaneously connected to two of the plurality of conductive regions 142. For example, the first electrode and the second electrode may be simultaneously connected to two adjacent conductive regions 142. In some embodiments, the plurality of conductive regions 142 may be positioned between the first conductive slip ring 143 and the second conductive slip ring 144.

In some embodiments, at least one battery core 170 may be connected between the two conductive regions 142. For example, a battery core 170 may be connected between two adjacent conductive regions 142. When the first electrode and the second electrode are respectively electrically connected to two conductive regions 142, a pathway may be formed between the battery core 170, the first electrode, the second electrode, and the bidirectional switching power supply 160. By rotating the gating disk 141 to drive the first electrode and the second electrode to be electrically connected to different conductive regions 142, respectively, a pathway may be formed between the bidirectional switching power supply 160 and different battery cores 170, thereby achieving a gating effect.

In some embodiments, the conductive region 142 may be fan-shaped. A center of the conductive region 142 may fall on an axis of the rotor 147.

The gating mechanism 140 may establish connectivity between the target battery core and the bidirectional switching power supply 160, thereby avoiding problems such as a poor heat dissipation, a high-power consumption, a small equalization current, and a great size caused by a switching matrix due to a setting of a plurality of switches.

In some embodiments, the system for charging and discharging management of the energy storage device 100 may also include a memory, a network, and/or a user terminal (not shown in the figures).

The memory may store data, commands, and/or any other information. In some embodiments, the memory may store data and/or commands related to the system for charging and discharging management of the energy storage device. For example, the memory may store charging data collected by the electrical signal collection circuitry 110 for the battery core 170 during charging.

The network may include any suitable wired or wireless network that facilitates an exchange of information and/or data. For example, the processor 130 and the electrical signal collection circuitry 110 may transmit voltage signals of at least one of the battery cores 170 via the network.

In some embodiments, a user may interact with the system for charging and discharging management of the energy storage device via a user terminal. Exemplary user terminals may include mobile devices, tablets, laptops, or any combination thereof.

More about the voltage signal, the state data, the charging parameter, the discharging parameter, the first work command, the first control command, the second work command, and the second control command may be referred to in FIG. 2-FIG. 5 and the related descriptions.

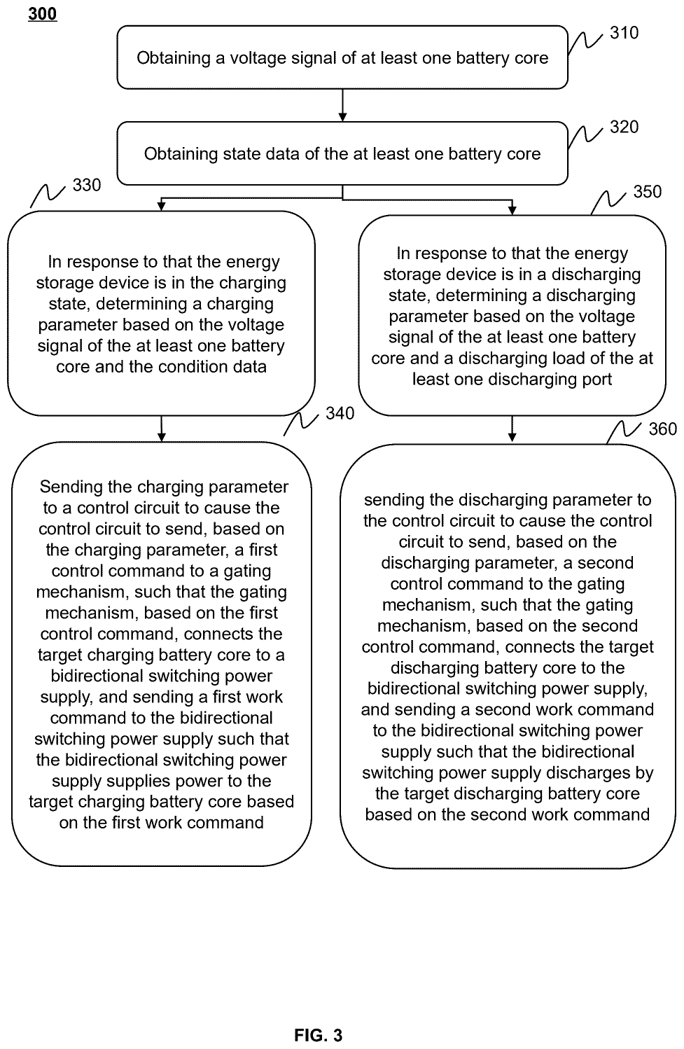

FIG. 3 is a flowchart illustrating an exemplary method for charging and discharging management of an energy storage device according to some embodiments of the present disclosure. As shown in FIG. 3, a process 300 may include the following steps. In some embodiments, the process 300 may be executed by a processor.

Step 310, obtaining a voltage signal of at least one battery core.

The voltage signal refers to data that characterizes a current voltage of the battery core.

In some embodiments, the processor may obtain the voltage signal of at least one battery core through an electrical signal collection circuit. For example, the processor may obtain the voltage signal of each battery core in real time or periodically through the electrical signal collection circuit and convert these voltage signal into digital format to storage in a memory.

Step 320, obtaining state data of the at least one battery core.

The state data refers to data that characterizes a state of environment surrounding the battery core. In some embodiments, the state data may include a temperature, a humidity, a dust accumulation, etc. where the at least one battery core is located.

The dust accumulation refers to an amount of dust or particles per unit volume accumulated in the environment surrounding the battery core. In some embodiments, the dust accumulation may affect a heat dissipation effect of the battery core, affecting charging temperature rising data of the battery core at different charging voltages, and thus affecting a safe charging constraint.

Similarly, the temperature and the humidity may affect the charging temperature rising data of the battery core at different charging voltages, which affects the safe charging constraint.

In some embodiments, the processor may obtain the state data for each battery core via the state monitoring device. For example, a temperature sensor, a humidity sensor, and a dust sensor in the state monitoring device may obtain the state data for each battery core in real time or periodically and convert the state data into electrical signals. The electrical signals may be subsequently transmitted to the processor via wired or wireless transmission, and the processor, after receiving these electrical signals, may convert them into specific values to be stored in a memory.

In some embodiments, in response to that the energy storage device is in a charging state, the processor may perform steps 330-step 340. The charging state refers to a state in which there is an external voltage input at a charging port.

Step 330, in response to that the energy storage device is in the charging state, determining a charging parameter based on the voltage signal of the at least one battery core and the condition data.

The charging parameter refers to a relevant parameter involved in a charging process. In some embodiments, the charging parameter may include a target charging battery core, and the charging voltage of the target charging battery core.

The target charging battery core refers to the battery core to be charged. In some embodiments, the gating mechanism may need to connect the target charging battery core to a bidirectional switching power supply before the target charging battery core is charged. In some embodiments, a number of the target charging battery core may be at least one.

The charging voltage of the target charging battery core refers to an input voltage of each of the at least one target charging battery core. A magnitude of the charging voltage may be controlled in a certain range to ensure that the battery core is able to safely and efficiently receive electrical energy.

In some embodiments, the processor may perform a stair segmentation on a charging battery core into stair segments based on the obtained voltage signal. A difference between the voltage signal of each of the stair segments may not be more than a preset voltage difference threshold.

In some embodiments, the preset voltage difference threshold may be preset based on manual experience.

For example, the processor may first take the at least one battery core in the stair segment with the lowest voltage signal (e.g., stair segment 1) as the target charging battery core for charging. Then, when the battery core in the stair segment 1 charges to the battery core whose voltage signal is not lower than a second low-voltage stair segment (e.g., a stair segment 2), the processor may take both the battery core in the stair segment with the lowest voltage signal and the battery core in the second low-voltage stair segment as the target charging battery core for charging. And so on until all battery cores are fully charged or, alternatively, the charging process is terminated externally.

In some embodiments, the processor may perform statistics based on historical data to determine a preferred charging voltage curve with an optimal charging effect of the battery core.

The optimal charging effect refers to charging with minimal loss to the battery core. For example, the charging with the lowest impact on a health state of the battery core.

A horizontal coordinate of the preferred charging voltage curve may be the voltage signal of the battery core, and a vertical coordinate may be the preferred charging voltage. The preferred charging voltage curve may indicate the charging voltage that minimizes a loss to the battery core under different voltage signals of the battery core. In some embodiments, the processor may construct a preferred charging voltage curve based on the historical data.

In some embodiments, the processor may select a corresponding preferred charging voltage in the preferred charging voltage curve based on the voltage signal of the battery core. In some embodiments, the processor may select the preferred charging voltage as the charging voltage for the target charging battery core.

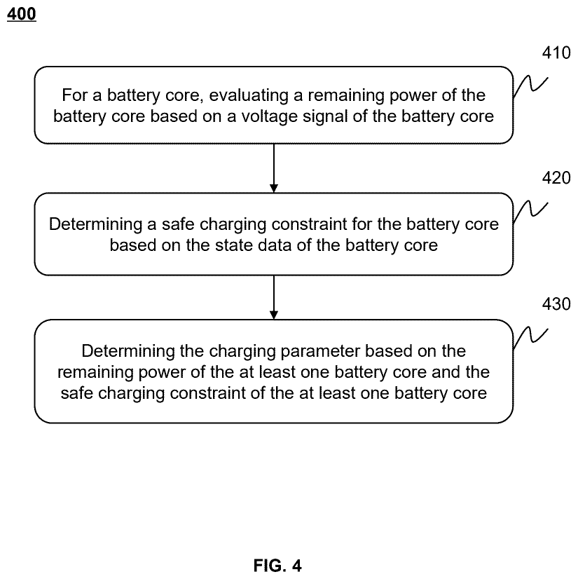

In some embodiments, the processor may determine a remaining power and the safe charging constraint of the at least one battery core, and thus determine the charging parameter. For more contents on determining the charging parameter, please refer to FIG. 4 and the associated descriptions.

Step 340, sending the charging parameter to a control circuit to cause the control circuit to send, based on the charging parameter, a first control command to a gating mechanism, such that the gating mechanism, based on the first control command, connects the target charging battery core to a bidirectional switching power supply, and sending a first work command to the bidirectional switching power supply such that the bidirectional switching power supply supplies power to the target charging battery core based on the first work command.

The first control command refers to a command that instructs the gating mechanism to connect the target charging battery core to the bidirectional switching power supply. The connecting the target charging battery core to the bidirectional switching power supply ensures that electrical energy is able to flow correctly from the bidirectional switching power supply to the target charging battery core, thereby realizing the charging process.

In some embodiments, the processor may send the charging parameter (e.g., the target charging battery core) to the control circuit, and the control circuit may generate, based on the charging parameter, the first control command and send the first control command to the gating mechanism.

The first work command refers to a command that instructs the bidirectional switching power supply to supply power to the target charging battery core. After receiving the first work command, the bidirectional switching power supply may output the electrical energy to the target charging battery core to ensure that the electrical energy flows safely from the bidirectional switching power supply to the target charging battery core.

In some embodiments, the processor may send the charging parameter (e.g., the target charging battery core and the charging voltage of the target charging battery core) to the control circuit, and the control circuit may generate, based on the obtained target battery core and the charging voltage of the target battery core, a first work command, and send the first work command to the bidirectional switching power supply.

In some embodiments, in response to that the energy storage device is in a discharging state, the processor may perform steps 350 to 360. The discharging state refers to a state in which there is voltage output at the discharging port.

Step 350, in response to that the energy storage device is in a discharging state, determining a discharging parameter based on the voltage signal of the at least one battery core and a discharging load of the at least one discharging port.

The discharging port refers to an interface in the energy storage device used to output the electrical energy. In some embodiments, when the energy storage device is in the discharging state, the electrical energy may be transferred through the discharging port to an external device for use. The external device refers to a device requires the electrical energy.

The discharging load refers to a discharge voltage requirement of the discharging port. Different discharging loads may correspond to different target discharging battery cores.

In some embodiments, different discharging ports may correspond to different discharging loads, and when the external device is connected to a certain discharging port, the discharging port may discharge according to the corresponding discharging load, thus determine the discharging load for the current discharging.

The discharging parameter refers to relevant parameters involved in the discharging process. In some embodiments, the discharging parameter may include the target discharging battery core.

In some embodiments, the processor may select one or more battery cores with total voltage signals above the discharging load of the discharging ports as the target discharging battery cores. For example, the processor may obtain the voltage signals of each battery core, and then sort the voltage signals in a descending order based on the voltage signal. The processor may further select one or more battery cores with the highest sorted total voltage signals above the discharging load as the target discharging battery cores.

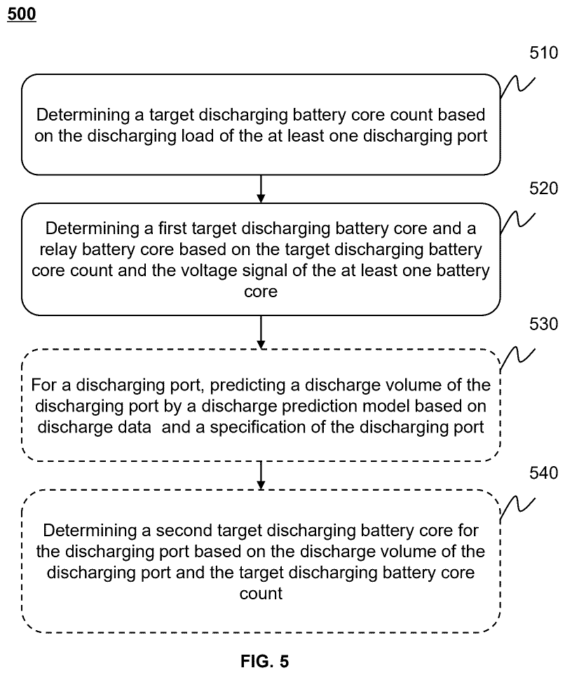

In some embodiments, the processor may determine a first target discharging battery core based on a count of the target discharging battery cores and a voltage signal of the at least one battery core; and determine a second target discharging battery core for the discharging port based on the discharge volume of the discharging port and the target discharging battery core count. For more contents on determining the first target discharging battery core and the second target discharging battery core, please refer to FIG. 5 and the related descriptions.

Step 360, sending the discharging parameter to the control circuit to cause the control circuit to send, based on the discharging parameter, a second control command to the gating mechanism, such that the gating mechanism, based on the second control command, connects the target discharging battery core to the bidirectional switching power supply, and sending a second work command to the bidirectional switching power supply such that the bidirectional switching power supply discharges by the target discharging battery core based on the second work command.

The second control command refers to a command that instructs the gating mechanism to connect the target discharging battery core to the bidirectional switching power supply. The connecting the target discharging battery core to the bidirectional switching power supply may ensure that electrical energy flows correctly from the target discharging battery core, thereby realizing the discharging process.

In some embodiments, the processor may send the discharging parameter (e.g., the target discharging battery core) to the control circuit, and the control circuit may generate, based on the discharging parameter, the second control command and send the second control command to the gating mechanism.

The second work command refers to a command that instructs the bidirectional switching power supply to supply power to the target discharging battery core. Upon receipt of the second work command, the bidirectional switching power supply may be discharged by the target discharging battery core to ensure that electrical energy safely flows from the target charging battery core to the bidirectional switching power supply, and thus to the external device.

In some embodiments, the processor may send the discharging parameter (e.g., the target discharging battery core) to the control circuit, and the control circuit may generate, based on the target discharging battery core, a second work command and send the second work command to the bidirectional switching power supply.

In some embodiments of the present disclosure, by monitoring the voltage signal and the state data of the battery core, the charging parameter and the discharging parameter of the battery core may be determined in a timely and reasonable manner, which ensures an overall operating life of the energy storage device and reduces a failure rate. By controlling the charging and discharging process of the battery core through various commands, an efficiency of the charging and discharging management of the energy storage device may be improved.

It may be noted that the foregoing description of the process 300 is intended to be exemplary and illustrative only and does not limit the scope of application of the present disclosure. For those skilled in the art, various corrections and changes may be made to the process 300 under the guidance of the present disclosure. However, these corrections and changes remain within the scope of the present disclosure.

FIG. 4 is a flowchart illustrating an exemplary process for determining a charging parameter as according to some embodiments of the present disclosure. As shown in FIG. 4, a process 400 may include the following steps. In some embodiments, the process 400 may be executed by a processor.

Step 410, for a battery core, evaluating a remaining power of the battery core based on a voltage signal of the battery core.

For more contents on the voltage signal, please refer to the descriptions in FIG. 3.

The remaining power refers to a remaining usable power in the battery core. In some embodiments, the remaining power may be expressed as a percentage of the remaining electrical energy to a battery capacity.

In some embodiments, the processor may obtain the remaining power in a plurality of ways. In some embodiments, during a discharging process of the battery core, the processor may pre-collect a voltage signal change of the battery core and plot a power-voltage change curve between the remaining power and the voltage. The processor may determine the corresponding remaining power in the power-voltage change curve based on a real-time monitored voltage signal. For example, during a discharge process with a preset power, it takes a total of 5 hours from full charge to complete discharge. The remaining power of the battery may be inversely proportional to a discharge time, with 80% remaining power after one hour of discharge, 60% remaining power after two hours of discharge, 40% remaining power after three hours of discharge, and 20% remaining power after four hours of discharge. The remaining power may be 0% after five hours of discharge. The processor may monitor the voltage signal of the battery core at different time points (e.g., every hour, every half an hour, etc.) to obtain the voltage and the remaining power at these time points, and use the data to plot the power-voltage change curve.

In some embodiments, the system for charging and discharging management of the energy storage device may further include a memory.

The memory refers to a structure used for data storage. In some embodiments, the memory may be configured within the processor. In some embodiments, the memory may be communicatively coupled to the processor. The processor may read data from the memory. For more contents on the memory, please refer to the description in FIG. 1.

In some embodiments, the electrical signal collection circuitry may also be configured to collect charging data of the battery core during charging and store the charging data in the memory.

The charging data refers to the relevant parameters of the battery core during charging. as another example, at least one of an input voltage, an output current, etc. of the battery core during charging.

In some embodiments, the processor may evaluate a health state of the battery core based on historical charging data, a historical voltage signal, and adjust the remaining power based on the health state.

The historical charging data refers to the charging data generated by the battery core within a historical time period.

In some embodiments, the processor may determine the historical charging data in a plurality of ways. For example, at least one of obtaining manual input, reading from the memory, etc.

The historical voltage signal refers to the voltage signal generated by the battery core within the historical time period. For more contents on the voltage signal, please refer to the description in FIG. 3.

The health state refers to the related data used to indicate a health degree of the battery core. For example, the health state may be expressed as the ratio of an actual capacity of the battery core to a designed capacity.

The designed capacity refers to the maximum amount of power that the battery core is able to hold when it is designed. For example, the designed capacity may be 10,000 mAh, 20,000 mAh, etc. In some embodiments, the processor may obtain the designed capacity in various ways. For example, at least one of obtaining manual input, obtaining from a vendor, etc.

In some embodiments, there may be at least one historical charge record. In some embodiments, for a single historical charge record, the processor may determine, based on the historical charging data, an actual charging volume of the historical charge record, determine a battery core recovery volume based on the historical voltage signal, and determine a reference health state based on the actual charging volume and the battery core recovery volume. Furthermore, the processor may determine the health state of the battery core based on the reference health state corresponding to the at least one historical charge record.

The historical charge record refers to the charging record generated by the battery core during a historical time period. In some embodiments, the historical charge record may include the historical charging data and the historical voltage signal. It may be noted that the historical charging data and the historical voltage signal may correspond in time. For example, if the historical charging data is for a night of May 10 from 10:00 p.m. to 12:00 a.m., the voltage signal may also be the voltage signal of the night of May 10 from 10:00 p.m. to 12:00 a.m. The charging data for each time point in that period may correspond to the voltage signal one by one.

In some embodiments, the processor may determine the historical charge record in various ways. For example, by obtaining manual input, obtaining from the historical data, etc.

The actual charging volume refers to an amount of power that is actually input into the battery core when the battery core performs a charging behavior.

In some embodiments, the processor may obtain the actual charging volume in a plurality of ways. For example, the actual charging volume may be calculated based on an integration of the voltage and current of the charge over time. In some embodiments, the actual charging volume may be indicated in an absolute value (mAh).

The battery core recovery volume refers to an amount of power that is actually recovered from the battery core when the battery core performs a charging behavior. In some embodiments, the battery core recovery volume may be expressed as a percentage of the amount of power that is actually recovered from the battery core in a total amount of power.

In some embodiments, the processor may obtain the battery core recovery volume in various ways. For example, the processor may determine, based on a power voltage change curve, a first remaining power before charging of the battery core, and a second remaining power after charging of the battery core. The processor may calculate a difference between the second remaining power and the first remaining power, and use the difference as the battery core recovery volume. For more contents on the charge-voltage change curve, please refer to the descriptions above.

In some embodiments, for a single historical charge record, the processor may determine a reference health state based on the actual charging volume and the battery core recovery volume. In some embodiments, the processor may determine a theoretical power volume for the battery core recovery based on the battery core recovery volume and the designed capacity of the battery core. The processor may calculate a ratio of the actual charging volume to the theoretical power volume, and use the ratio as the reference health state of the battery core. For example, if a certain battery core has a designed capacity of 10,000 mAh, and the battery core recovery volume of 40%, then the theoretical power volume for the battery core recovery may be 4,000 mAh. If an actual charging volume is 3600 mAh, then the reference health state may be 3600 mAh÷4000 mAh=90%. In some embodiments, the processor may determine an average of the reference health state corresponding to at least one historical charge record as the health state of the battery core.

By determining the reference health state based on the actual charging volume and the battery core recovery volume, and determining the health state of the battery core, an accuracy of the determined health state may be improved.

In some embodiments, the processor may correct the remaining power based on the health state. For example, the processor may calculate a product of the health state and the remaining power, and use the product as a corrected remaining power. Correcting the remaining power using the health state to correlate the remaining power with the health of the battery core improves the accuracy of the determined remaining power.

Step 420, determining a safe charging constraint for the battery core based on the state data of the battery core.

For more contents on the state data, please refer to the descriptions of FIG. 3.

The safe charging constraint refers to a maximum charging voltage set to ensure a safe charging.

In some embodiments, the processor may determine the safe charging constraint in various ways, e.g., at least one of obtaining a manual input, obtaining from historical data, etc.

In some embodiments, the processor may determine the safe charging constraint by a preset safety rule.

The preset safety rule refers to a preset rule used to determine the safe charging constraint. The preset safety rule may include a maximum charging voltage corresponding to different state data.

In some embodiments, the processor may determine the preset safety rule based on the historical data. For example, the processor may filter different historical state data and the corresponding historical maximum charging voltage from the historical data. Based on the different historical state data and the corresponding historical maximum charging voltage, a query table may be constructed, and the query table may be used as a preset safety rule. The processor may determine the maximum charging voltage based on the state data by querying the preset safety rule, and take the maximum charging voltage as the safe charging constraint.

In some embodiments, the processor may construct a state vector based on the temperature, the humidity, and the dust accumulation of environment where the battery core is located, and then determine a charging temperature rising data for the battery core at different charging voltages in a temperature rising vector database through vector matching. Subsequently, the safe charging constraint may be determined based on the charging temperature rising data.

The state vector refers to a vector constructed from the temperature, the humidity, and the dust accumulation of environment in which the battery core is located. In some embodiments, elements of the state vector may include the temperature, the humidity, and the dust accumulation. In some embodiments, the processor may obtain the temperature, the humidity, and the dust accumulation in various ways. For example, the processor may control a state monitoring device (e.g., a temperature sensor, a humidity sensor, a dust sensor, etc.) to detect the temperature, the humidity, and the dust accumulation, and obtain data detected by the sensor.

In some embodiments, the processor may divide at least one battery core into a plurality of the stair segments based on the remaining power of the at least one battery core. Based on the remaining power of the battery core, the target stair segment corresponding to the battery core may be determined. The processor may construct, in response to that the adjacent battery core corresponding to the target stair segment contains the adjacent battery core of the battery core, a state vector based on the remaining power of the battery core and the remaining power of the adjacent battery core, as well as the temperature, the humidity, and the dust accumulation of environment where the battery core is located and the temperature, the humidity, and the dust accumulation of environment where the adjacent battery core is located.

The stair segment refers to dividing the plurality of battery cores into groups according to a preset rule, with the remaining power of the battery cores within each group falling within the same interval range. For more contents on the stair segments, please refer to the related description below.

The target stair segment refers to the stair segment where the target battery core is located after the plurality of the battery cores are divided into the stair segments. In some embodiments, the processor may determine the target stair segment corresponding to the target battery core based on the interval range of the remaining power corresponding to the stair segment and the remaining power of the target battery core. For example, the remaining power of a first stair segment may be 0%-10%, and the remaining power of a second stair segment may be 10%-20%. When the remaining power of the target battery core is 13%, the processor may determine that the target stair segment corresponding to the target battery core is the second stair segment.

The adjacent battery core may be a combination of at least two battery cores that do not have other battery cores spaced between them. In some embodiments, the processor may number the plurality of the battery cores. The processor may further record relative positions of the plurality of the battery cores, the corresponding numbers of the battery cores, and a distribution of the numbers. The processor may determine, based on the relative positions of the plurality of the battery cores and the numbering, whether the adjacent battery cores are included in the target stair segment.

Understandably, as the processor determines the target charging battery core by dividing the stair segments, consideration of the adjacent battery cores herein may take into account whether the battery cores corresponding to the target stair segment contain the adjacent battery cores of the battery cores that requires determining the safe charging constraint.

In some embodiments, the processor may obtain a result of the stair segmentation according to the remaining power, determine the target stair segment corresponding to the battery core that requires determining the safe charging constraint, and thereby determine whether the battery cores corresponding to the target stair segment contain the adjacent battery cores of the battery cores that requires determining the safe charging constraint. In response to that the battery cores corresponding to the target stair segment contain the adjacent battery cores of the battery cores that requires determining the safe charging constraint, the processor may select the adjacent battery cores, determine the maximum value of the state data for each of the battery cores for the battery cores whose safe charging constraint requires to be determined, and the minimum value of the remaining power, to construct the state vector.

For example, in the target stair segment that includes a total of 10 battery cores, 3 of which may be adjacent to the battery cores require to determine the safe charging constraint, and the processor may determine the 3 adjacent battery cores as the adjacent battery cores. The processor may further determine the maximum temperature, the maximum humidity, the maximum dust accumulation, and the minimum remaining power for each of the battery cores requires determining the safe charging constraint, so as to construct a state vector.

Understandably, as the higher the temperature, the higher the humidity, the higher the dust accumulation, and the lower the remaining power, and the battery core is more prone to heat generation, the maximum temperature, the maximum humidity, the maximum dust accumulation, and the minimum remaining power for each battery core requires determining the safe charging constraint, and the adjacent battery cores may be selected to construct the state vector.

As the heat generation of the adjacent battery cores affects each other, and the remaining power varies, an internal resistance of the battery may be different, leading to varying heat generation. When constructing the state vector, considering the remaining power and the state parameters of the battery core requires determining the safe charging constraint and the adjacent battery cores, an accuracy of constructing the state vector may be improved.

The charging temperature rising data refers to data related to a temperature rising of the battery core during charging. In some embodiments, the charging temperature rising data may include a rate of temperature rising of the battery core at different charging voltages.

In some embodiments, the processor may determine the charging temperature rising data for the battery core at different charging voltages in a temperature rising vector database through vector matching.

The temperature rising vector database refers to a vector database constructed based on battery temperature rising data during an actual charging in the historical data. For more contents on the temperature rising vector database, please refer to the related description below. In Table 1, the first column represents a temperature rising rate corresponding to a first reference vector at a first charging voltage, a second charging voltage, a third charging voltage, etc.; the second column represents the temperature rising rate corresponding to a second reference vector at the first charging voltage, the second charging voltage, the third charging voltage, etc.; and the third column represents the temperature rising rate corresponding to a third reference vector under the first charging voltage, the second charging voltage, the third charging voltage, etc.

| The first reference | The second reference | The third reference | |
|---|---|---|---|
| vector | vector | vector | . . . |
| Temperature rising | Temperature rising | Temperature rising | . . . |
| rate corresponding | rate corresponding | rate corresponding | |
| to the first | to the first | to the first | |
| charging voltage | charging voltage | charging voltage | |
| Temperature rising | Temperature rising | Temperature rising | . . . |
| rate corresponding | rate corresponding | rate corresponding | |
| to the second | to the second | to the second | |
| charging voltage | charging voltage | charging voltage | |
| Temperature rising | Temperature rising | Temperature rising | . . . |
| rate corresponding | rate corresponding | rate corresponding | |
| to the third | to the third | to the third | |
| charging voltage | charging voltage | charging voltage | |
| . . . | . . . | . . . | . . . |

In some embodiments, the processor may determine the safe charging constraint based on the charging temperature rising data. For example, the processor may calculate a plurality of charging times required for the battery core to be fully charged from the current remaining power under different charging voltage conditions. The processor may calculate a final battery core temperature when the battery core is fully charged based on the corresponding temperature rising rate and the charging time of the battery core, as well as an initial temperature of the battery core. The initial temperature refers to the temperature in the state data of the battery core. The processor may compare the final battery core temperature and a temperature alert value, determine the charging voltage corresponding to the final battery core temperature that is lower than the temperature alert value as an optional charging voltage, and determining the charging voltage corresponding to the final battery core temperature that is not lower than the temperature alert value as a hazardous voltage. The processor may use the maximum value of the optional charging voltages as the safe charging constraint. The temperature alert value refers to a preset value for determining whether the temperature of the final battery core meets the requirements. The processor may obtain the temperature alert value from the manufacturer.

By determining a safe charging constraint, the maximum charging voltage of the battery core may be limited to avoid damage caused by the battery core being subjected to an excessive voltage. Determining the safe charging constraint based on vector matching may improve an accuracy of determining the safe charging constraints.

Step 430, determining the charging parameter based on the remaining power of the at least one battery core and the safe charging constraint of the at least one battery core.

For more contents on the charging parameters, please refer to the descriptions of FIG. 3.

In some embodiments, the processor determines the charging parameter may including determining the target charging battery core and the charging voltage.

In some embodiments, the processor may determine the target charging battery core in various ways.

In some embodiments, the processor may divide the battery core into the stair segments based on the remaining power of the battery core to obtain a plurality of stair segments. For example, a battery core with a remaining power between 0% and 10% may be divided into the first stair segment, a battery core with a remaining power between 10% and 20% may be divided into the second stair segment, . . . , a battery core with a remaining power between 90% and 100% may be divided into the tenth stair segment. In some embodiments, for the battery core within each stair segment, a difference between the maximum value of the remaining power and the minimum value of the remaining power may be less than or equal to a power difference threshold. The power difference threshold may be preset. The processor may determine the power difference threshold in various ways. For example, the processor may determine the power difference threshold based on at least one of the historical data, the experience, etc.

In some embodiments, after the processor divides the plurality of the battery cores into the stair segments, the processor may use at least one battery core within the stair segment with the lowest remaining power as the target charging battery core. For example, at least one battery core within the first stair segment may be taken as the target charging battery core to be charged. In some embodiments, the charging time of the battery cores within the same stair segment may be the same or different.

When the remaining power of all the battery cores in the stair segment with the lowest remaining power is not less than the minimum remaining power of the battery cores in the adjacent stair segment, the processor may take the at least one battery core within the stair segment with the lowest remaining power, and the adjacent stair segment as the target charging battery core. Then the processor may proceed in an analogous manner until the charging ends or all of the battery cores are fully charged. For example, after charging all the battery cores in the first stair segment for a certain period, the remaining power of all the battery cores may not be less than the minimum remaining power in the second stair segment. The processor may use the at least one battery core within the first stair segment and the second stair segment as the target charging battery core. Then the processor may proceed in an analogous manner until the charging ends or all of the battery cores are fully charged.

In some embodiments, the processor may determine the charging voltage in various ways.

In some embodiments, the processor may perform statistics based on the historical data to determine a preferred charging voltage curve with an optimal charging effect of the battery core.

The optimal charging effect refers to minimizing a loss to the battery core during charging. For example, minimizing an impact of charging on the health state of the battery core.

A horizontal coordinate of the preferred charging voltage curve may be the remaining power of the battery core, and a vertical coordinate may be the preferred charging voltage. The preferred charging voltage curve may represent a charging voltage corresponding to minimizing the loss to the battery core under different remaining power conditions. In some embodiments, the processor may construct a preferred charging voltage curve based on the historical data.

In some embodiments, the processor may select a corresponding preferred charging voltage in the preferred charging voltage curve based on the remaining power of the battery core. In some embodiments, the processor may select the smaller value between the preferred charging voltage and the corresponding safe charging constraint of the battery core as the charging voltage.

For more contents on the safe charging constraints, please refer to the previous description of the present disclosure.

In some embodiments, the processor may predict future discharge data based on the historical discharge data by a discharge demand model, and determine the charging parameter based on the future discharge data, the remaining power, and the safe charging constraint.

The discharge demand model refers to a model that is used to predict the future discharge data. In some embodiments, the discharge demand model may be a machine learning model. For example, the discharge demand model may be a recurrent neural networks (RNN) model, etc.

An input to the discharge demand model may include the historical discharge data and an output may include the future discharge data.

The discharge data refers to relevant data generated when the battery core discharges. For example, at least one of a discharge voltage, a discharge current, a discharge period, etc., when the battery core discharges. In some embodiments, the processor may obtain the discharge data in various ways, such as, for example, by controlling a sensor detection, etc.

The historical discharge data refers to the discharge data generated during the discharge of a battery core in a historical period. In some embodiments, the processor may obtain the discharge data in various ways, such as, for example, obtain the discharge data from historical data, etc.

In some embodiments, the historical discharge data may include the discharge data for a plurality of battery cores contained in the system for charging and discharging management of the energy storage device. In some embodiments, the historical discharge data may include at least one discharge data sequence, and the discharge data sequence may include the discharge voltages, the discharge currents, and the discharge periods, etc., of the plurality of battery cores over time, e.g., [(a1, b1, c1), (a2, b3, c2) . . . ]. The a1, a2 represent the discharge periods, the b1, b2 represent the discharge voltages, and the c1, c2 represent the discharge currents.

The future discharge data refers to predicted discharge data generated when a battery core is discharged in a future time period. In some embodiments, the future discharge data may include at least one sequence of discharge data similar to the at least one sequence of discharge data included by the historical discharge data, which is not described herein.

In some embodiments, the processor may obtain a first training dataset. The first training dataset may include a plurality of the first training samples and first labels corresponding to the first training samples.

In some embodiments, the processor may perform a plurality of iterations. At least one round of the iterations may include the following steps.

Selecting one or more first training samples from a training dataset, inputting the one or more first training samples into an initial discharge demand model, and obtaining one or more model prediction outputs corresponding to the first training samples.

Calculating a value of a loss function by substituting the model prediction outputs corresponding to the first training samples, and the first labels corresponding to the first training samples into a formula for a predefined loss function.

Reversely updating model parameters in the initial discharge demand model based on the value of the loss function. In some embodiments, the processor may reversely update the model parameters in the initial discharge demand model in various ways. For example, the update may be based on a gradient descent method.

When an end-of-iteration condition is satisfied, the processor may end the iteration and obtain a trained discharge demand model. The end-of-iteration condition may include a convergence of the loss function, or that a number of iterations reaches a threshold, etc.

In some embodiments, the processor may obtain the first training dataset in various ways. For example, the processor may construct the first training dataset by taking the historical discharge data during a first historical time period as the first training sample, and taking the historical discharge data during a second time period as the first label for the first training sample. In some embodiments, the second historical time period may be later than the first historical time period.

In some embodiments, the first training dataset may further include randomly generated expended training samples to expand the first training dataset.

In some embodiments, the expended training samples may be randomly generated in various ways based on the first training samples. For example, for each first training sample in the first training dataset, if the temperature, the humidity, and the dust accumulation of the environment when collecting the first training sample satisfy a preset condition, at least a portion of the discharge voltage and the discharge current in the historical discharge data of the first training sample may be randomly increased or decreased within a preset amplitude (e.g., randomly increased or decreased by 1%-10%, etc.), so as to obtain an expended training sample. In some embodiments, the label corresponding to the expended training sample and the first label may be the same. The preset magnitude may be set artificially, for example, the preset magnitude may be 1%, 2%, 5%, etc. In some embodiments, the preset condition may include at least one of the temperature, the humidity, and the dust accumulation being greater than a corresponding preset threshold. The preset threshold may be set artificially. When the temperature, the humidity, or the dust accumulation is great, it may affect a measurement accuracy of the discharge voltage and the discharge current and result in an existence of a measurement error of the discharge voltage and the discharge current. By setting the preset condition, the first training sample with a measurement error may be screened out, and by adjusting the discharge voltage and the discharge current of the first training sample within a preset amplitude range, the number of training samples may be expanded so as to make the trained discharge demand model more accurate.

Using the discharge demand model to predict the future discharge data and determine the charging parameter based on the future discharge data may improve the accuracy of the charging parameter determined. When training the discharge demand model, the first training dataset may be expanded by employing an expended training sample to improve the training accuracy of the discharge demand model.

In some embodiments, the processor may determine the charging parameter based on the future discharge data, the remaining power, and the safe charging constraint.

For more contents on the remaining power, and the safe charging constraint, please refer to the above descriptions.

In some embodiments, after the processor divides the plurality of the battery cores into the stair segments according to the remaining power, the processor may calculate a number of the battery cores required for power supply based on the future discharge data.

In some embodiments, the processor may determine the target charging battery core based on the number of the battery cores required for power supply. For example, each stair segment may be sorted from the highest to the lowest remaining power, and the stair segment with the highest remaining power (e.g., the tenth stair segment) may be prioritized, and the battery core within the stair segment may be used as the target charging battery core. If the number of the battery cores required for power supply is greater than the number of the battery cores in the stair segment, then the battery cores in the adjacent stair segment (e.g., the ninth stair segment) may be selected as the target charging battery cores. And so on, until the determined number of the target charging battery core is greater than the number of the battery core required for power supply. After the target charging battery core is charged to a level of power capable of satisfying a future discharging need, the subsequent charging parameter may be determined according to the manner for determining the charging parameter based on the remaining power of at least one battery core and the safety charging constraint of the at least one battery core.

For more on contents on the stair segments, and determining the charging parameter based on the remaining power of the at least one battery core and the safe charging constraint of the at least one battery core, please refer to the preceding descriptions.

In some embodiments, the processor may determine, based on the future discharge data, a target power volume that requires to be achieved before a future discharge time. The processor may select a first target charging battery core based on the target power volume, the remaining power of the at least one battery core, and a discharge equalization of the at least one battery core in a combination of the historical target discharging battery core, and determine the charging voltage of the first target charging battery core.

The target power volume refers to a power requirement to satisfy the future discharge data. In some embodiments, the target power volume may be a power requirement that one or more battery cores requires to satisfy.

In some embodiments, the processor may obtain the target power volume in various ways. For example, the discharge power for different discharge periods may be calculated based on the discharge voltage and the discharge current in the future discharge data, and the target power volume may be calculated based on the discharge power and discharge duration. Alternatively, the processor may calculate products of the discharge powers for different discharge periods and the corresponding discharge times, and use a sum of these products as the target power volume.

The first target charging battery core refers to the battery core that is prioritized for charging among the plurality of the target charging battery cores. In some embodiments, the first target charging battery core may include one or more battery cores.

The discharge equalization refers to a level of voltage stabilization when a plurality of the battery cores are combined to form a discharging battery core combination, and the discharging battery core combination discharges. In some embodiments, the discharge equalization may be positively correlated with a power supply capacity of the discharging battery core combination. That is, the worse the discharge equalization of the discharging battery core combination and the greater a voltage signal fluctuation, the worse the power supply capability of the discharging battery core combination, then, the discharging battery core combination may not be selected as the first target charging battery core.

For more contents on the discharging battery core combination, please refer to the descriptions of FIG. 5.

In some embodiments, the processor may determine the discharge equalization in various ways. For example, the processor may determine the discharge equalization based on a fluctuation frequency and a magnitude of the voltage signal when the discharging battery core combination is discharged. In some embodiments, the discharge equalization may be negatively correlated to the fluctuation frequency and the magnitude. In some embodiments, the processor may calculate the discharge equalization based on the fluctuation frequency and the magnitude by a first preset algorithm. For example, the first preset algorithm may include formula (1):

$${J}_{ℏ} = \frac{k}{P \times F} \qquad ( 1 )$$

where, Jₕ denotes the discharge equalization, P denotes the fluctuation frequency, F denotes the fluctuation magnitude, and k denotes a coefficient. In some embodiments, the processor may determine k in various ways. For example, from the historical data, etc.

In some embodiments, the processor may determine the first target charging battery core based on the discharge equalization.

In some embodiments, the processor may select, from a plurality of the historical target discharging battery core combinations, a battery core of the historical target discharging battery core combination whose discharge equalization is greater than an equalization threshold. In some embodiments, the processor may determine the equalization threshold in various ways, such as, for example, by human setting, etc.

The processor may perform the stair segmentation on the battery cores of the historical target discharging battery core combination whose discharge equalization is greater than the equalization threshold based on the remaining power. The processor may select at least one battery core in the stair segment with the highest remaining power as the first target charging battery core. For example, the processor may select 10 battery cores whose discharge equalization is higher than the equalization threshold. The processor may divide these 10 battery cores into the stair segments based on the remaining power and select a battery core in one of the stair segments with a higher remaining power as the first target charging battery core.

For more contents on the stair segment, please refer to the previous related description.

In some embodiments, the processor may determine the charging voltage of the first target charging battery core before the future discharge time based on a difference between the current remaining power and the target power volume of the first target charging battery core, as well as the future discharge time. For example, the remaining power of the first target charging battery core may be 20%, the target power volume may be 85%, and the future discharge time may be 5th-8th hour after a current moment. The processor may calculate a required charging voltage to charge the first target charging battery core from 20% to 85% in 5 hours, and charge the first target charging battery core to the target power volume using the charging voltage.

After the first target charging battery core reaches the target power volume, the processor may select a minimum value of the preferred charging voltage and the safe charging constraint corresponding to the first target charging battery core as a subsequent charging voltage of the first target charging battery core. For more contents on the preferred charging voltage and the safe charging constraint, please refer to the previous related descriptions.

In some embodiments, in response to that the an actual discharge operation is not monitored before a future discharge time, the processor may determine a second target charging battery core and the charging voltage of the second target charging battery core.

The second target charging battery core refers to a target charging battery core with a lower charging priority than the first target charging battery core among the plurality of the target charging battery cores. In some embodiments, a plurality of the second target charging battery cores may be charged in batches.

In some embodiments, if the actual discharging operation is not monitored, the processor may charge the second target charging battery core. In some embodiments, the processor may determine the second target charging battery core and the charging voltage of the second target charging battery core based on the remaining power of the at least one battery core, and the safe charging constraint of the at least one battery core, as described above. For more contents on determining the charging parameter based on the remaining power of the at least one battery core and the safe charging constraint of the at least one battery core, please refer to the previous related descriptions.

Determining the first target charging battery core based on the future discharge data may prioritize the charging of the first target charging battery core with the highest remaining power when there is a discharging operation in the future time period, so that the first target charging battery core with the highest remaining power may reach a target power volume that satisfies the discharging demand, in order to satisfy the discharging demand in the future time period and ensure a better discharge equalization. In this way, a situation of prioritizing the charging of the target charging battery core with the lowest remaining power may be avoided to prevent all battery cores from failing to satisfy the power requirement of the discharging operation. When the discharging operation does not actually exist, then the processor may switch to charge the second target charging battery core with the lowest remaining power to ensure that the plurality of battery cores synchronously or basically synchronously reach the target power volume after charging, thereby avoiding an overcharging and a damage to the target charging battery core.

Based on the remaining power of the battery core and the safe charging constraint, a reasonable charging parameter of the battery core may be determined, and the battery core may be charged in batches based on the remaining power of the battery cores while avoiding damage to the battery cores due to a high charging voltage.

It may be noted that the foregoing description of the process 400 is intended to be exemplary and illustrative only and does not limit the scope of application of the present disclosure. For those skilled in the art, various corrections and changes may be made to the process 400 under the guidance of the present disclosure. However, these corrections and changes remain within the scope of the present disclosure.

FIG. 5 is a flowchart illustrating an exemplary process for determining a target discharging battery core and a relay battery core according to some embodiments of the present disclosure. As shown in FIG. 5, a process 500 may include the following steps. In some embodiments, the process 500 may be executed by a processor.

In some embodiments, as the way in which steps 530-540 determine the second target discharging battery core takes a long time, a certain delay may be caused, which affects the user experience. Therefore, the processor may first temporarily supply power based on a first target discharging battery core determined in steps 510-520, and then, after a second target discharging battery core is determined in steps 530-540, the processor may switch the first target discharging battery core to the second target discharging battery core via a gating mechanism.

Step 510, determining a target discharging battery core count based on the discharging load of the at least one discharging port.

The target discharging battery core count refers to a minimum target discharging battery core count required to satisfy a discharge demand. In some embodiments, the target discharging battery core count may include a total number required for all the discharging ports, as well as a respective number required for each discharging port.

In some embodiments, the processor may determine the target discharging battery core count by querying a preset quantity relationship table. For example, the processor may query the preset quantity relationship table based on the discharging load of each discharging port to determine a number of the battery cores corresponding to each discharging port. The number of the battery cores corresponding to each discharging port and a sum of the number of the battery cores of all the discharging ports may be determined as the target discharging battery core count. The preset quantity relationship table may be a design parameter of the energy storage device. The discharging ports of different discharging loads in the energy storage device may be preset with a required number of the discharging battery cores, and when the discharging port discharges, the corresponding number of the battery cores may be selected for discharge.

Step 520, determining a first target discharging battery core and a relay battery core based on the target discharging battery core count and the voltage signal of the at least one battery core.

The first target discharging battery core refers to the at least one battery core that discharges when the discharging port is just accessed. In some embodiments, the processor may evaluate the remaining power of the at least one battery core based on the voltage signal of the at least one battery core. Then, the processor may determine the target discharging battery core count corresponding to the discharging port based on a user-selected discharging port, and then arrange the at least one battery core in order of high to low power level, select the top-ranked target discharging battery core count of battery cores as the first target discharging battery cores. For more contents on evaluating the remaining power of a battery core, please refer to FIG. 4 and the related descriptions.

The relay battery core refers to a battery core that takes over the first target discharging battery core for discharging when a certain target discharging battery core reaches a power alert value. In some embodiments, if there is a certain target discharging battery core whose power level is below the power alert value, the processor may obtain the power level of the battery cores other than the first target discharging battery core, arrange at least one of the other battery cores in order of high to low power level, and select the top-ranked target discharging battery core count of battery cores as the relay battery core.

In some embodiments, the power alert value may be a percentage of power corresponding to a capacity of the battery core. For example, the power alert value may be 5%, 10%, 15%, etc. When the remaining power of a certain battery core is less than 10% of the capacity of the battery core, the power of the battery core may reach the power alert value.

The target discharging battery core count may be determined through the discharging load, and then the first target discharging battery core may be determined, which efficiently satisfies the discharge demand. When the second target discharging battery core is not determined, the discharge may be carried out through the first target discharging battery core in time to satisfy the discharge demand of an external device. By discharging the relay battery core instead of the first target discharge battery core with lower power, an overuse of the battery core may be avoided, and a damage on the battery core caused by an over-discharging may be prevented, thus extending an overall service life of the battery core.

Step 530: for a discharging port, predicting a discharge volume of the discharging port by a discharge prediction model based on discharge data and a specification of the discharging port.

The discharge prediction model refers to a model for predicting a discharge volume from the discharging port. In some embodiments, the discharge prediction model may be a machine learning model, such as an RNN model, etc.

In some embodiments, an input to the discharge prediction model may include a specification of the discharging port and discharge data.

In some embodiments, an output of the discharge prediction model may include a discharge volume from the discharging port.

The discharge data refers to data corresponding to the discharge of the first target discharging battery core. In some embodiments, the discharge data may include a discharge current and a discharge voltage based on the discharge of the first target discharging battery core at the time of discharge.

In some embodiments, the specification of the discharging port may include the maximum discharge voltage that the discharging port supports.

The discharge volume refers to a total amount of electrical energy released from the discharging port.

In some embodiments, the processor may obtain a second training dataset, which includes a plurality of second training samples and corresponding second labels. In some embodiments, the processor may obtain the second training dataset in various ways. For example, the processor may use various approaches to obtain the second training dataset. For instance, the processor may take historical discharging port specifications and historical discharge data from a historical discharge record as the second training samples, and take actual discharge volumes corresponding to the second training samples as the second labels, thereby constructing the second training dataset.

In some embodiments, the processor may train an initial discharge prediction model through various rounds of iterations. At least one round of the iterations may include: selecting one or more second training samples from the training dataset, inputting the one or more second training samples into the initial discharge prediction model, and obtaining model prediction outputs corresponding to the one or more second training samples; calculating a value of the loss function by substituting the model prediction outputs corresponding to the one or more second training samples, and the second labels corresponding to the one or more second training samples into a formula of a predefined loss function; reversely updating model parameters of the initial discharge prediction model based on a value of the loss function using an optimization algorithm such as a gradient descent method. When an end-of-iteration condition is satisfied (e.g., the loss function converges, a number of iterations reaches a second preset iteration threshold, etc.), the processor may end the iterations and obtain a trained discharge prediction model.

In some embodiments, the processor may adjust a learning rate of the discharge prediction model during iterations of the initial discharge prediction model. The learning rate may control an updating magnitude of the discharge prediction model parameters during the training process. A suitable learning rate may improve a training efficiency while ensuring the convergence of the discharge prediction model.

In some embodiments, the processor may categorize the second training samples, calculate proportions of the different types of the second training samples, and set the learning rate for training the discharge prediction model based on the proportions.

For example, the processor may classify the second training samples based on a sample discharging port specification, and sample discharge data in the second training samples using a bucket algorithm, and calculate a ratio value of a number of different types of the second training samples in a total number of different types of second training samples. The higher the ratio value of a type of the second training samples, the higher the ratio of the type of historical discharge data in a user's historical discharge record. This indicates that the type of discharge scenario is frequently used by the user. Therefore, the learning rate of the type of training samples may be increased, so as to improve a matching degree between the discharge prediction model and the user.

Predicting the discharge of the discharging port through the discharge prediction model allows for a more accurate determination of the discharge volume of the discharging port in the future, which in turn allows for the determination of a more reasonable second target discharging battery core.

Step 540, determining a second target discharging battery core for the discharging port based on the discharge volume of the discharging port and the target discharging battery core count.

The second target discharging battery core refers to a battery core used to succeed the first target discharging battery core. In some embodiments, when the second target discharging battery core is determined, the gating mechanism may disconnect between the first target discharging battery core and a bidirectional switching power supply, and simultaneously connect the second target discharging battery core to the bidirectional switching power supply, allowing the second target discharging battery core to perform the discharge.

In some embodiments, the processor may determine the second target discharging battery core for the discharging port based on the discharge volume at the discharging port and the target discharging battery core count. For example, for a discharging port, the processor may select the battery core whose total remaining power is not less than the discharge volume of the discharging port, and satisfies the target discharging battery core count, as the second target discharging battery core. For example, the processor may select a battery core, from the first target charging battery cores, whose total remaining power is not less than the discharge volume of that discharging port, and which satisfies the target discharging battery core count, as the second target discharging battery core.

In some embodiments, the processor may determine a plurality of discharging battery core combinations based on the remaining power of the at least one battery core using a clustering algorithm under a constraint of the target discharging battery core count; determine the discharge battery core combination corresponding to the at least one discharging port based on the discharge volume of the at least one discharging port, and the remaining power of the battery cores in the plurality of discharge battery core combinations; and determine the second target discharging battery core for the discharging port based on the discharge battery core combination corresponding to the at least one discharging port.

The discharging battery core combination refers to a combination of the discharging battery cores that performs the discharging. In some embodiments, the processor may determine the plurality of the discharging battery core combinations based on the remaining power of the at least one battery core, under the constraint of the target discharging battery core count, by clustering the at least one battery core via a clustering algorithm.

In some embodiments, the processor may determine a number of clusters in the clustering algorithm based on the number of the discharging ports. The clusters may include at least one discharging battery core combination corresponding to the discharging port that is discharging, and the discharging battery core combinations of the remaining discharging ports that do not need to be discharged at this time. For example, the processor may set the number of clusters to M, and M=number of the discharging ports+1.

In some embodiments, the processor may cluster the at least one battery core based on the clustering algorithm (e.g., a K-means clustering algorithm) under the constraint that a number of members in the respective cluster is less than the target discharging battery core count, thereby obtaining M discharging battery core combinations.

In some embodiments, the processor may determine a remaining power for each of the plurality of the discharging battery core combinations, and arrange the remaining powers corresponding to the plurality of the discharging battery core combinations in order from largest to smallest, and, based on the ordering, the processor may determine the discharging battery core combinations corresponding to the discharging ports. For example, the processor may determine, based on the foregoing order of arrangement, the discharging battery core combination with the highest remaining power as the discharging port with the greatest discharge volume, and the discharging battery core combination with the second remaining power as the discharging port with the second greatest charge volume, etc. In this way, the discharging battery core combination corresponding to the at least one discharging port may be determined.

In some embodiments, the processor may determine the second target discharging battery core for the discharging port based on the discharging battery core combination corresponding to the at least one discharging port. For example, the processor may use at least one battery core of the discharging battery core combination corresponding to the discharging port selected by the user, as the second target discharging battery core.

By obtaining the discharging battery core combination through a clustering algorithm, combining the battery cores into different discharging battery core combinations, and then determining the second target discharging battery core, it may be ensured that a plurality of the battery cores with approximately the same power volume supply power to the same discharging port together to maintain a discharge balance of these battery cores.

In some embodiments of the present disclosure, a temporary power supply may be performed first based on the first target discharging battery core to avoid delays and improve user experience. After the second target discharging battery core is determined, the first target discharging battery core may then be switched to the second target discharging battery core by the gating mechanism to make the discharging parameter more reasonable.

The foregoing descriptions of steps 510-540 are for the purpose of exemplification and illustration only and does not limit the scope of application of the present disclosure. For those skilled in the art, various corrections and changes may be made to steps 510-540 under a guidance of the present disclosure. However, these corrections and changes remain within the scope of the present disclosure.

In some embodiments, the processor may monitor, a discharge change of the at least one discharging port in real time; in response to that a first discharging port ends a discharge and the second target discharging battery core corresponding to the first discharging port satisfies a condition for a continued power supply, obtain the discharge data for a second discharging port; determine an electrical stability of the second discharging port based on the discharge data of the second discharging port; and in response to that the electrical stability satisfies a stability condition, control the target discharging battery core corresponding to the first discharging port to perform an auxiliary power supply.

In some embodiments, the processor may monitor the discharge change of at least one discharging port in real time. The discharge change may include a discharge change current. For example, the processor may obtain a current value of the discharging port in real time based on a current sensor deployed at the discharging port.

The first discharging port refers to a discharging port that has stopped discharging. For example, when the processor detects that the current value of a certain discharging port is 0, or that the current value of a certain discharging port is below a very low current threshold, the processor may determine that the discharging port has stopped discharging. The very low current threshold may be set artificially.

The condition for the continued power supply refers to the minimum requirement for continuing the discharge. For example, the condition for the continued power supply may be that a sum of the remaining power of the second target discharging battery cores corresponding to the first discharging port is above a power alert value.

For more contents on the power alert value, please refer to the descriptions above.

The second discharging port refers to a discharging port other than the first discharging port that is discharging among the at least one discharging port. In some embodiments, when the first discharging port stops discharging, the processor may detect whether the other discharging ports are discharging to find the second discharging port.

In some embodiments, when the processor detects that a current value of a certain discharging port is not 0, or that the current value of a certain discharging port is above a very low current threshold, the processor may determine that the discharging port is discharging.

The electrical stability refers to a value (e.g., the voltage, the current, etc.) that indicates the stability of the discharging port during the supply process. In some embodiments, the processor may determine the electrical stability based on a changing trend of the discharge data. For example, if the changing trend of the voltage and current in the discharge data is constant (e.g., appliances directly use the power) or gradually decreasing (e.g., charging other electrical devices), which is consistent with a normal changing trend of discharge data, then the electrical stability may be high. If the changing trend is that the voltage and current fluctuate high and low, the electrical stability may be low. The more frequent the fluctuations and the higher a degree of fluctuation, the lower the electrical stability. Exemplarily, the processor may determine the electrical stability of the second discharging port by querying a vector database based on the discharge data (e.g., vectors including currents and voltages at different points in time) of the second discharging port.

The stability condition refers to a condition for determining whether the second discharging port requires an auxiliary power supply from the first discharging port. For example, the stability condition may be that the electrical stability of the second discharging port is less than a stability threshold. The stability threshold may be set based on manual experience.

In some embodiments, in response to the electrical stability satisfying the stability condition, the processor may control the second target discharging battery core corresponding to the first discharging port to perform the auxiliary power supply. For example, the processor may connect the second target discharging battery core corresponding to the first discharging port to the bidirectional switching power supply via the gating mechanism, and control the second target discharging battery core corresponding to the first discharging port to supply power to the second discharging port through the bidirectional switching power supply. Next, the processor may select the battery core with the highest remaining power and the best health state among the battery cores of the second discharge port, and the second target discharge battery cores corresponding to the first discharge port, which meets the target discharge battery core count corresponding to the second discharge port, for power supply.

In some embodiments of the present disclosure, when there is a discharging port stopping discharge, and the second target discharging battery core corresponding to the discharging port satisfies the condition for a continued power supply, the auxiliary power supply may be performed for the other power supply ports whose electrical stability satisfies the stability condition through the second target discharging battery core corresponding to the discharging port, in order to maintain the discharge balance of the plurality of the battery cores and extend the service life of the battery core.

One or more embodiments of the present disclosure further provide a computer-readable storage medium, the storage medium storing computer instructions, and when the computer reads the computer instructions in the storage medium, the computer operates any one of the method for charging and discharging management of an energy storage device described in any of the embodiments above.

In addition, certain features, structures, or characteristics of one or more embodiments of the present disclosure may be suitably combined.

Some embodiments use numbers to describe the number of components, attributes, and it should be understood that such numbers used in the description of the embodiments are modified in some examples by the modifiers “about,” “approximately,” or “substantially.” Unless otherwise noted, the terms “about,” “approximately,” or “substantially” indicate that a ±20% variation in the stated number is allowed. Correspondingly, in some embodiments, the numerical parameters used in the disclosure and claims are approximations, which can change depending on the desired characteristics of individual embodiments. In some embodiments, the numerical parameters should take into account the specified number of valid digits and employ general place-keeping. While the numerical domains and parameters used to confirm the breadth of their ranges in some embodiments of this disclosure are approximations, in specific embodiments such values are set to be as precise as possible within a feasible range.

In the event of any inconsistency or conflict between the descriptions, definitions, and/or use of terminology in the materials cited in this disclosure and those described in this disclosure, the descriptions, definitions, and/or use of terminology in this disclosure shall prevail.

What is claimed is:

1. A system for charging and discharging management of an energy storage device, including an electrical signal collection circuit, a state monitoring device, a processor, a gating mechanism, a control circuit, and a bidirectional switching power supply; wherein
the electrical signal collection circuit is configured to collect a voltage signal of at least one battery core in the energy storage device;
the state monitoring device is configured to monitor state data of the at least one battery core, the state data including a temperature, a humidity, and a dust accumulation of environment where the at least one battery core is located;
the processor is configured to:
in response to that the energy storage device is in a charging state, determine a charging parameter and the state data based on the voltage signal of the at least one battery core, and send the charging parameter to the control circuit, the charging parameter including a target charging battery core, and a charging voltage of the target charging battery core;
in response to that the energy storage device is in a discharging state, determine a discharging parameter based on the voltage signal of the at least one battery core, a discharging load of at least one discharging port, and send the discharging parameter to the control circuit, the discharging parameter including a target discharging battery core;
the control circuit is configured to send a first control command to the gating mechanism, and a first work command to the bidirectional switching power supply based on the charging parameter; or send a second control command to the gating mechanism, and a second work command to the bidirectional switching power supply based on the discharging parameter;
the gating mechanism is configured to connect the target charging battery core to the bidirectional switching power supply based on the first control command; or to connect the target discharging battery core to the bidirectional switching power supply based on the second control command; and
the bidirectional switching power supply is configured to supply power to the target charging battery core based on the first work command; or to discharge power by the target discharging battery core based on the second work command.

2. The system of claim 1, wherein the processor is further configured to:
for any one of the at least one battery core,
evaluate a remaining power of the battery core based on the voltage signal of the battery core;
determine a safe charging constraint for the battery core based on the state data of the battery core; and
determine the charging parameter based on the remaining power of the at least one battery core and the safe charging constraint of the at least one battery core.

3. The system of claim 2, wherein the processor is further configured to:
construct a state vector based on the temperature, the humidity, and the dust accumulation of the environment where the battery core is located;
determine, by vector matching, charging temperature rising data for the battery core under different charging voltages from a temperature rising vector database; and
determine the safe charging constraint based on the charging temperature rising data.

4. The system of claim 3, wherein the processor is further configured to:
divide the at least one battery core into a plurality of stair segments based on the remaining power of the at least one battery core;
determine a target stair segment corresponding to the battery core based on the remaining power of the battery core; and
in response to that the battery core corresponding to the target stair segment includes an adjacent battery core of the battery core, construct the state vector based on the remaining powers of the battery core and the remaining powers of the adjacent battery core, as well as the temperature, the humidity, and the dust accumulation of the environment where the battery core is located and the temperature, the humidity, and the dust accumulation of the environment where the adjacent battery core is located.

5. The system of claim 2, wherein the processor is further configured to:
predict future discharge data based on historical discharge data by a discharge demand model, the discharge demand model being a machine learning model; and
determine the charging parameter based on the future discharge data, the remaining power, and the safe charging constraint.

6. The system of claim 5, wherein the processor is further configured to:
determine a target power volume that needs to be achieved before a future discharge time based on the future discharge data;
select a first target charging battery core based on the target power volume, the remaining power of the at least one battery core, a discharge equalization of the at least one battery core in a historical target discharging battery core combination, and determine a charging voltage of the first target charging battery core; and
in response to that no actual discharge operation is monitored before the future discharge time, determine a second target charging battery core, and a charging voltage of the second target charging battery core.

7. The system of claim 2, wherein the system further includes a memory;
the electrical signal collection circuit is further configured to collect charging data of the battery core during charging and store the charging data in the memory;
the processor is further configured to:
assess a health state of the battery core based on historical charging data and a historical voltage signal; and
correct the remaining power based on the health state.

8. The system of claim 7, wherein a count of a historical charge record is at least one, the historical charge record including the historical charging data and the historical voltage signal, the processor is further configured to:
for any one of the at least one historical charge record,
determine an actual charging volume for the historical charge record based on the historical charging data;
determine a battery core recovery volume based on the historical voltage signal;
determine a reference health state based on the actual charging volume and the battery core recovery volume; and
determine the health state of the battery core based on the reference health state corresponding to the at least one historical charge record.

9. The system of claim 1, wherein the processor is further configured to:
determine a target discharging battery core count based on the discharging load of the at least one discharging port; and
determine a first target discharging battery core and a relay battery core based on the target discharging battery core count and the voltage signal of the at least one battery core.

10. The system of claim 9, wherein the processor is further configured to:
for any one of the at least one discharging port,
predict a discharge volume of the discharging port by a discharge prediction model based on discharge data and a specification of the discharging port, the discharge prediction model being a machine learning model, and the discharge data being the data corresponding to discharge of the first target discharging battery core; and
determine a second target discharging battery core for the discharging port based on the discharge volume of the discharging port and the target discharging battery core count.

11. The system of claim 10, wherein the processor is further configured to:
determine a plurality of discharging battery core combinations based on a remaining power of the at least one battery core by clustering the at least one battery core using a clustering algorithm under a constraint of the target discharging battery core count;
determine the discharging battery core combination corresponding to the at least one discharging port based on the discharge volume of the at least one discharging port, and the remaining power of the battery cores in the plurality of discharging battery core combinations; and
determine the second target discharging battery core for the discharging port based on the discharging battery core combination corresponding to the at least one discharging port.

12. The system of claim 11, wherein the processor is further configured to:
monitor a discharge change of the at least one discharging port in real time;
in response to that a first discharging port ends discharge and the second target discharging battery core corresponding to the first discharging port satisfies a condition for a continued power supply, obtain the discharge data for a second discharging port, the second discharging port being a discharging port of the at least one discharging port other than the first discharging port;
determine an electrical stability of the second discharging port based on the discharge data of the second discharging port; and
in response to that the electrical stability satisfies a stability condition, control the target discharging battery core corresponding to the first discharging port to perform an auxiliary power supply.

13. A method for charging and discharging management of an energy storage device, wherein the method is implemented by a processor, and the method comprising:
obtaining a voltage signal of at least one battery core;
obtaining state data of the at least one battery core, the state data including a temperature, a humidity, a dust accumulation of environment where the at least one battery core is located;
in response to that the energy storage device is in a charging state,
determining a charging parameter based on the voltage signal and the state data of the at least one battery core, the charging parameter comprising a target charging battery core, and a charging voltage of the target charging battery core;
sending the charging parameter to a control circuit to cause the control circuit to send, based on the charging parameter, a first control command to a gating mechanism, such that the gating mechanism, based on the first control command, connects the target charging battery core to a bidirectional switching power supply, and sending a first work command to the bidirectional switching power supply such that the bidirectional switching power supply supplies power to the target charging battery core based on the first work command;
in response to that the energy storage device is in a discharging state,
determining a discharging parameter based on the voltage signal of the at least one battery core, a discharging load of the at least one of discharging port, the discharging parameter comprising a target discharging battery core; and
sending the discharging parameter to the control circuit to cause the control circuit to send, based on the discharging parameter, a second control command to the gating mechanism, such that the gating mechanism, based on the second control command, connects the target discharging battery core to the bidirectional switching power supply, and sending a second work command to the bidirectional switching power supply such that the bidirectional switching power supply discharges by the target discharging battery core based on the second work command.

14. The method of claim 13, wherein the determining a charging parameter based on the voltage signal of the at least one battery core and the state data includes:
for any one of the at least one battery core,
evaluating a remaining power of the battery core based on the voltage signal of the battery core;
determining a safe charging constraint for the battery core based on the state data of the battery core; and
determining the charging parameter based on the remaining power of the at least one battery core and the safe charging constraint of the at least one battery core.

15. The method of claim 14, wherein the determining a safe charging constraint for the battery core based on the state data of the battery core includes:
constructing a state vector based on the temperature, the humidity, and the dust accumulation of the environment where the battery core is located;
determining, by vector matching, charging temperature rising data for the battery core under different charging voltages from a temperature rising vector database; and
determining the safe charging constraint based on the charging temperature rising data.

16. The method of claim 15, wherein the constructing a state vector based on the temperature, the humidity, and the dust accumulation of the environment where the battery core is located includes:
dividing the at least one battery core into a plurality of stair segments based on the remaining power of the at least one battery core;
determining a target stair segment corresponding to the battery core based on the remaining power of the battery core; and
in response to that the battery core corresponding to the target stair segment includes an adjacent battery core of the battery core, constructing the state vector based on the remaining powers of the battery core and the remaining powers of the adjacent battery core, as well as the temperature, the humidity, and the dust accumulation of the environment where the battery core is located and the temperature, the humidity, and the dust accumulation of the environment where the adjacent battery core is located.

17. The method of claim 14, wherein the determining the charging parameter based on the remaining power of the at least one battery core and the safe charging constraint of the at least one battery core includes:
predicting future discharge data based on historical discharge data by a discharge demand model, the discharge demand model being a machine learning model; and
determining the charging parameter based on the future discharge data, the remaining power, and the safe charging constraint.

18. The method of claim 17, wherein the determining the charging parameter based on the future discharge data, the remaining power, and the safe charging constraint includes:
determining a target power volume that needs to be achieved before a future discharge time based on the future discharge data;
selecting a first target charging battery core based on the target power volume, the remaining power of the at least one battery core, a discharge equalization of the at least one battery core in a historical target discharging battery core combination, and determine a charging voltage of the first target charging battery core; and
in response to that no actual discharge operation is monitored before the future discharge time, determining a second target charging battery core, and a charging voltage of the second target charging battery core.

19. The method of claim 14, wherein the evaluating the remaining power of the battery core based on a voltage signal of the battery core includes:
collecting charging data of the battery core during charging and store the charging data in the memory;
assessing a health state of the battery core based on historical charging data and a historical voltage signal; and
correcting the remaining power based on the health state.

20. A non-transitory computer-readable storage medium storing computer instructions, wherein when reading the computer instructions from the storage medium, a computer implements the method for charging and discharging management of an energy storage device as claimed in claim 1.
